(19) United States
(12) Patent Application Publication
(10) Pub. No.: US 2011/0052871 A1
(43) Pub. Date: Mar. 3, 2011

(54) HEAT DISSIPATING MATERIAL INCLUDING CARBON SUBSTRATE WITH NANOMETER-ORDER UNEVEN STRUCTURE AND ITS MANUFACTURING METHOD

(75) Inventor: Takahiro MATSUMOTO, Yokohama (JP)

(73) Assignee: STANLEY ELECTRIC CO., LTD., Tokyo (JP)

(21) Appl. No.: 12/868,758

(22) Filed: Aug. 26, 2010

(30) Foreign Application Priority Data
Aug. 26, 2009 (JP) 2009-195354

(51) Int. Cl. B32B 3/10; C09K 5/00; G03F 7/20; C23F 1/00

(52) U.S. Cl. 428/141; 428/195.1; 252/71; 430/323; 216/67

(57) ABSTRACT

A heat dissipating material includes a carbon substrate having an uneven structure on a surface thereof, and a size of the uneven structure is on the nanometer-order.

This application claims the priority benefit under 35 U.S.C. §119 to Japanese Patent Application No. JP2009-195354 filed on Aug. 26, 2009, which disclosure is hereby incorporated in its entirety by reference.

### BACKGROUND

1. Field

The presently disclosed subject matter relates to a heat dissipating material and its manufacturing method.

2. Description of the Related Art

Attention has been paid to cooling of heat generating components, such as semiconductor elements mounted on electronic/electrical equipment, i.e., computers and the like, solar cells, and power converters and inverters used in electric vehicles.

In order to cool a heat generating component, one approach is to fit a fan in a body on which the heat generating component is mounted, thus cooling the body by driving the fan. Another approach is to fit a heat dissipating medium such as a heat pipe, a heat sink, a fin or a fan in the heat generating component, so that heat generated from the heat generating component is transferred via the heat dissipating medium to the outside. In this case, a good thermal conduction material such as copper or aluminum is arranged between the heat generating component and the heat dissipating medium, so that heat generated from the heat generating component is transferred via the thermal conduction material to the heat dissipating medium which convects the heat transferred to the heat dissipating medium to the outside.

However, recently, since heat generating components have been highly powered, and also, their space has been reduced, their heat generating power density tends to increase. Particularly, when the body for mounting the heat generating component is small-sized, the space for mounting the heat dissipating medium is small-sized, so that the convection heat transfer rate becomes lower to increase the temperature of the heat generating component, i.e., to reduce the performance thereof.

In order to effectively cool the above-mentioned heat generating component under an insufficient convection condition, especially in vacuum, heat dissipating materials have been applied to reduce the temperature of the heat generating components.

Therefore, as a powerful heat dissipating medium in order to reduce the temperature of modern sophisticated heat generating devices, it is expected to have a high emissivity of heat radiation as well as a high convection heat transfer coefficient in heat dissipating materials.

A first heat dissipating material is comprised of a ceramic substrate made of SiC or AlN (see: JP2-7445).

In the above-described first prior art heat dissipating material, however, the emissivity of these ceramic substrates is low on the order of 0.8. Also, the ceramic substrate is basically formed by sintering about 10 to 100 μm-radius ceramic powder with a suitable binder. As a result, since air gaps would be generated between the heat generating component and the ceramic substrate, the contact characteristics therebetween would deteriorate, thus reducing the heat dissipation amount. Further, since the thermal expansion coefficient of the ceramic substrate is very small, the ceramic substrate would often be peeled off the heat generating component due to the difference in thermal expansion coefficient between the ceramic substrate and the heat generating component. Furthermore, since the degree of hardness of SiC or AlN of the ceramic substrate is very large, it is hard to process, i.e., cut or polish the ceramic substrate. Thus, the manufacturing cost would be increased.

A second prior art heat dissipating material is comprised of a diamond substrate with a high thermal conductivity of about 1000 to 2000 W/m·K (see: JP2008-222468A).

In the above-described second prior art heat dissipating material, however, the emissivity of a diamond substrate is low on the order of 0.5. Also, in the same way as in the ceramic substrate, since the thermal expansion coefficient of the diamond substrate is very small, the diamond substrate would often be peeled off the heat generating component due to the difference in thermal expansion coefficient between the diamond substrate and the heat generating component. Further, since the degree of hardness of the diamond substrate is very high, it is hard to process, i.e., cut or polish the diamond substrate. Thus, the manufacturing cost would be increased. Furthermore, since the diamond substrate is much more expensive than the ceramic substrate, the manufacturing cost would further be increased.

A third prior art heat dissipating material is comprised of a flexible graphite film (see: JP2009-107904A).

In the above-described third prior art heat dissipating material, the emissivity of a graphite substrate is relatively high on the order of 0.9. However, since the graphite substrate has anisotropic property of thermal conduction, the graphite film is less heat-conductive between the heat generating component and the graphite substrate. Also, since the graphite film is made of sintered carbon powder, the structure of the graphite film is porous. Therefore, the graphite film is fragile and low heat conductive. Thus, the heat dissipating power of the graphite substrate is generally low compared to an inorganic substrate such as a ceramic substrate or a diamond substrate.

A fourth prior art heat dissipating material is comprised of good heat radiating heat-resistant, chemical-resistant and inexpensive carbon nantotubes (CNTs) (see: JP2004-10978A).

In the above-described fourth prior art heat dissipating material, the emissivity of CNTs are high on the order of 0.97. However, since CNTs are made of carbon, CNTs are less heat-conductive than an inorganic substrate such as the ceramic substrate or the diamond substrate. Also, since CNTs are brittle and hydrophobic, the contact characteristics between CNTs and the heat generating component would deteriorate. In this case, it is common to coat CNTs with fluid dispersion material on a metal substrate such as a copper substrate. Therefore, since the contact characteristics between the metal substrate and the CNTs are bad, the CNTs would be peeled off the metal substrate. Otherwise, since the metal substrate does not combine with the metal substrate at an atomic level, a thermal resistance would be generated therebetween so that a thermal conduction loss would be generated. Note that, although a paste may be inserted between the metal substrate and the CNTs to prevent the CNTs from being peeled off the metal substrate, such a paste per se is a thermal resistance so that a thermal conduction loss is also generated. Further, if the CNTs are heated to a temperature higher than 400° C., the CNTs would be explosively burned.

### SUMMARY

The presently disclosed subject matter seeks to solve one or more of the above-described problems.

According to the presently disclosed subject matter, a heat dissipating material includes a carbon substrate having an uneven structure on a surface thereof, and a size of the uneven structure is on the nanometer-order. Thus, the reflectivity at a wavelength from 0.3 to 2 μm including that of a visible ray becomes low, and also, the reflectivity at a wavelength from 2 to 50 μm including those of far infrared rays becomes low, resulting in the high emissivity.

Also, in a method for manufacturing a heat dissipating material, a process is performed upon a carbon substrate to have an uneven structure on a surface thereof. A size of the uneven structure is on the nanometer-order.

According to the presently disclosed subject matter, since the reflectivity at a wavelength including those of the visible rays and far infrared rays becomes low, the emissivity by radiation can be enhanced. Also, since the carbon substrate is used as the heat dissipating material, the heat dissipating material is hardly melted, and the thermal conduction hardly deteriorates. Further, no explosive burning of the heat dissipating material would occur.

### BRIEF DESCRIPTION OF THE DRAWINGS

The above and other advantages and features of the presently disclosed subject matter will be more apparent from the following description of certain embodiments, taken in conjunction with the accompanying drawings, wherein:

FIG. 1 is a graph illustrating a reflectivity and blackbody radiation spectrum required for an ideal heat dissipating material;

FIG. 2 is a flowchart for forming a nanometer-order uneven structure on a graphite substrate of a heat dissipating material according to the presently disclosed subject matter;

FIG. 3A is a scanning electron microscope (SEM) photograph of the graphite substrate before the plasma etching step of FIG. 2;

FIG. 3B is a SEM photograph of the graphite substrate after the plasma etching step of FIG. 2;

FIG. 4 is a graph illustrating a reflectivity of the surface of the graphite substrate at a wavelength from 0.3 to 2 μm before and after the plasma etching step of FIG. 2;

FIG. 5 is a graph illustrating a reflectivity of the surface of the graphite substrate at a wavelength from 2 to 15 μm before and after the plasma etching step of FIG. 2; and

FIG. 6 is a flowchart of a modification of the flowchart of FIG. 2.

### DETAILED DESCRIPTION OF EXEMPLARY EMBODIMENTS

An embodiment of the method for manufacturing a heat dissipating material according to the presently disclosed subject matter will now be explained with reference to the attached drawings.

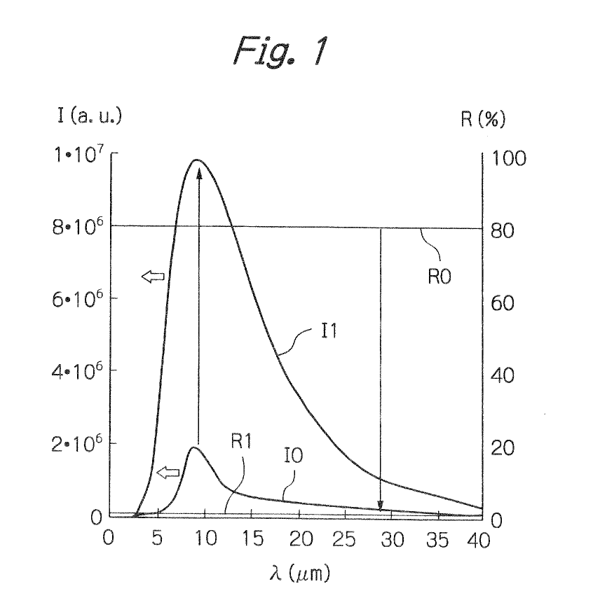

In FIG. 1, which is a graph illustrating a reflectivity required for an ideal heat dissipating material, the operational principle of a heat dissipating material according to the presently disclosed subject matter uses a radiating cooling operation by far infrared rays of an absorption energy of a complete black body. That is, as illustrated in FIG. 1 where λ is a wavelength, when the reflectivity R is high, i.e., R=R0 (=80%), energy absorbed by the ideal heat dissipating material is radiated to the outside in accordance with an emissivity I0 (=20%) of FIG. 1 at a room temperature of 300K; however, in this case, since the reflectivity R0 is high, the radiating efficiency is low due to the low emissivity. On the other hand, when the reflectivity R is low, i.e., R=R1 (=1%), an energy absorbed by the ideal heat dissipating material is radiated to the outside in accordance with an emissivity I1 (=99%) of FIG. 1 at a room temperature of 300K. In this case, since the reflectivity R1 is low, the emissivity is high. In other words, when the reflectivity is decreased, the emissivity I is increased, while, when the reflectivity R is increased, the emissivity I is decreased. In this relationship, the emissivity is represented by the following equation where the light transmittivity is almost 0,

I=1−R

In view of the foregoing, an ideal heat dissipating material has a reflectivity R as close to zero as possible at a wavelength λ from 0.3 to 50 μm, to increase the emissivity.

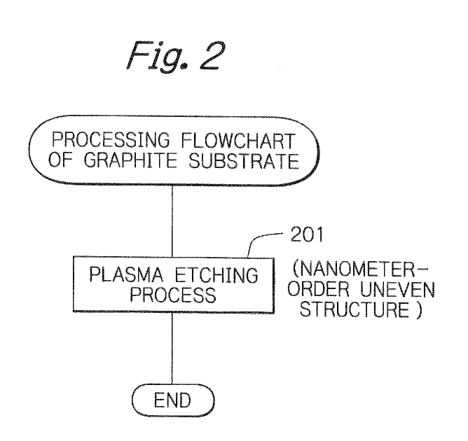

FIG. 2 is a flowchart for forming a nanometer-order uneven structure on a graphite substrate of a heat dissipating material according to the presently disclosed subject matter.

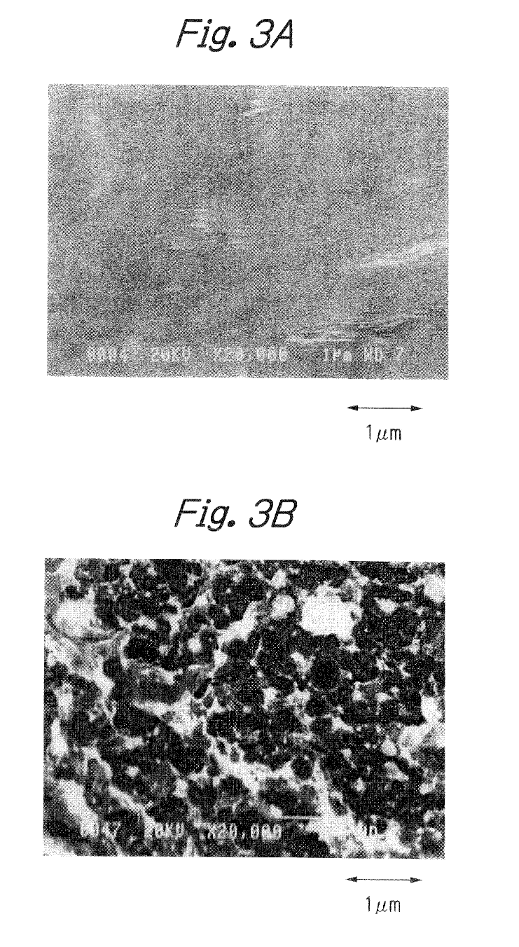

At step 201, a plasma etching process using hydrogen (H₂) gas as a processing gas is performed upon a graphite substrate whose mirror surface is as illustrated in FIG. 3A, to obtain a graphite substrate whose nanometer-order uneven surface is as illustrated in FIG. 3B. The plasma etching conditions are as follows:

Radio frequency (RF) power: 100 to 1000 W;

Pressure: 133 to 13300 Pa (1 to 100 Torr);

Flow rate of hydrogen: 5 to 500 sccm; and

Etching time: 1 to 100 minutes.

The graphite substrate of FIG. 3B has a nanometer-order uneven structure.

Note that the plasma etching process at step 201 of FIG. 2 may be an electron cyclotron resonance (ECR) process, a reactive ion etching (RIE) process or an atmospheric plasma etching process. Also, the processing gas may be Ar gas, N₂ gas, 0₂ gas, CF₄ gas and so on in addition to H₂ gas.

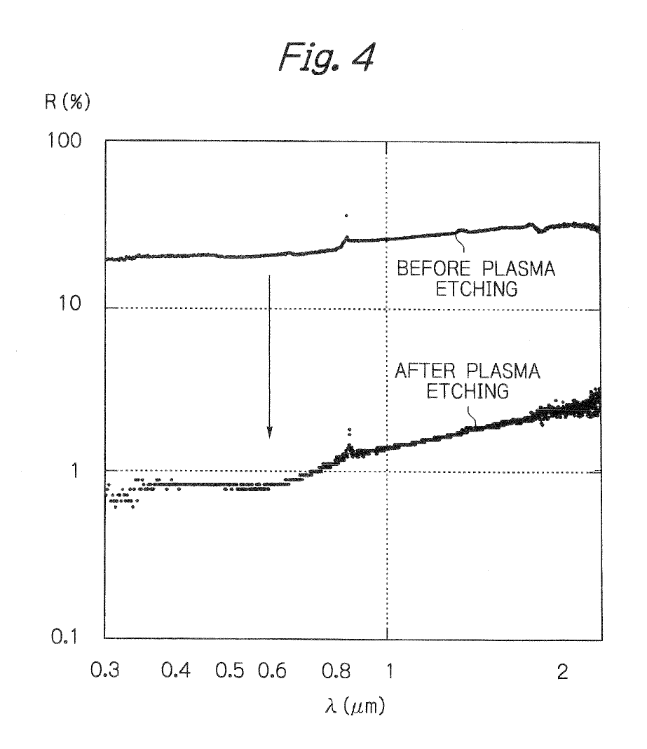

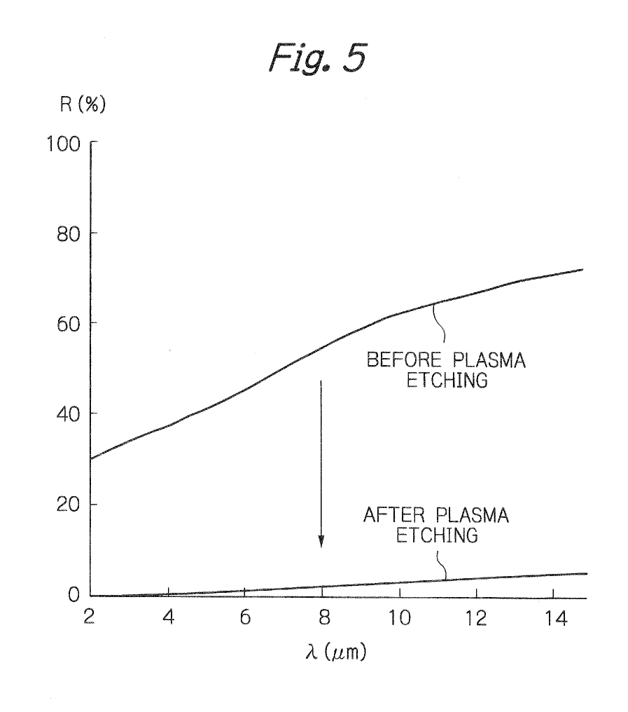

Thus, as illustrated in FIG. 4, the reflectivity at the wavelength λ from 0.3 to 2 μm including the wavelength of visible rays is changed by step 202 of FIG. 2 from 20 to 30% to less than 1%. Therefore, the absorption is maximum at the wavelength λ including the wavelength of the visible rays. Also, as illustrated in FIG. 5, the reflectivity at the wavelength λ from 2 to 15 μm of far infrared rays is changed by step 202 of FIG. 2 from 60% to less than 2%. Thus, the reflectivity characteristics as illustrated in FIGS. 4 and 5 are brought close to the reflectivity R1 of FIG. 1 for the ideal heat dissipating material. As a result, the plasma-etched graphite substrate can be used as a heat dissipating material.

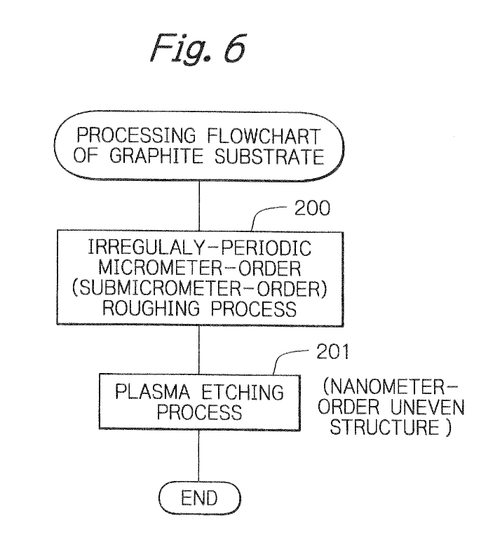

In FIG. 6, which is a modification of the flowchart of FIG. 2, a micrometer-order (or submicrometer-order) irregularly-periodic roughening step 200 is added before step 201 of FIG. 2.

At step 200, a roughening process by a mechanical roughening process using sandblast or the like or a surface roughening process using a high power laser such as a C0₂ laser, a yttrium-aluminum-garnet (YAG) laser or an excimer laser is performed upon the surface of the graphite substrate, to form a micrometer-order or submicrometer-order irregularly-periodic uneven structure on the surface of the graphite substrate, to substantially increase the surface area thereof, which would increase the emissivity.

Note that, at step 200 of FIG. 6, a large number of irregularly-periodic grooves on the micrometer-order or submicrometer-order can be formed at the surface of the graphite substrate instead of the irregularly-periodic uneven structure on the micrometer-order or submicrometer-order. For example, a photoresist pattern is formed on the surface of the graphite substrate by using a photomask with an irregularly-periodic pattern, and then, a plasma etching process such as an RIE process using H₂ gas and/or 0₂ gas is performed upon the graphite substrate with the photoresist pattern, which is finally removed. Otherwise, a cutting process using a mechanical ruling engine is performed upon the surface of the graphite substrate to form a micrometer-order or submicrometer-order irregularly-periodic spiked-holder (or pinholder) type unevenness on the surface of the graphite substrate, to thereby increase the surface area thereof. The above-mentioned spiked-holder type structure can be realized by forming a mold with a reverse spiked-holder type structure and then pouring liquid graphite material such as carbon black into the mold.

Note that, a regularly-periodic uneven structure of a micrometer-order or submicrometer-order may generate an adverse two-dimensional photonic crystal effect to increase the reflectivity for far infrared rays, i.e., to decrease the emissivity.

The measurement of the reflectivity at the wavelength λ from 0.3 to 3 μm of FIG. 4 was carried out by a spectrophotometer having an integral sphere with an inner face on which BaSO₄ particles are coated. On the other hand, the measurement of the reflectivity at the wavelength λ from 2 to 15 μm of FIG. 5 was carried out by a Fourier transformation infrared (FTIR) spectrophotometer having an integral sphere with an inner face on which gold (Au) for collecting far infrared rays is coated.

The inventor evaluated a heat dissipating material which is comprised of a graphite substrate having the above-mentioned nanometer-order uneven structure.

1) The heat dissipating material had a size of 10 cm×10 cm. In this case, since the surface of the nanometer-order uneven structure was porous as illustrated in FIG. 3B, the effective surface area which contributes to the heat radiation was about 0.02 m² (>0.01 m²). Also, it is assumed that the emissivity I was 98%, i.e., the reflectivity R was 2% (=at a surface temperature of 300° C.

2) It is assumed that a heat dissipating component was a power converter whose power was 5 kW and energy conversion efficiency was 98%, and then, this power converter generated 100 W. In this case, since the heat radiating amount S from the heat dissipating material followed the Stephan and Boltzmann radiation rule, the heat radiating amount S was represented by

S=(Ts⁴−Ta⁴)·A·I·σ

where Ts is an absolute temperature (K) at the surface of the heat dissipating material;

Ta is an absolute temperature (K) of the atmosphere;

A is a surface area of the heat dissipating material; and

σ is a Stephan and Boltzmann constant and is represented by

5.67×10⁻⁸ W/(m²·K⁴).

Therefore,

$$\begin{matrix}S = ( {( 300 + 273.15 )}^{4} - {( 23 + 273.15 )}^{4} ) \times 0.02 \times 0.98 \\ 5.67 \times {10}^{- 8} \\ = 111.387 W\end{matrix} \times$$

Thus, almost 100% of the heat generated from the 5 kW power converter was dissipated to the outside by the heat dissipating material according to the presently disclosed subject matter.

Note that by the fabrication of the nanometer-order uneven structure, the convection heat transfer ratio is also increased as well as the emissivity. This is due to the thermal transpiration effect in the confined nanometer-order uneven structure.

Metal can be combined into the above-mentioned graphite substrate to obtain a dense graphite substrate. Since the dense graphite substrate has a large toughness, the workability of the heat dissipating material and the contact characteristics between the heat dissipating material and the heat generating component would be improved, so that no gaps would be generated therebetween. Also, if insulation is required between a heat generating component and a heat dissipating material, an insulating graphite substrate can be used as such a heat dissipating material.

Also, note that the nanometer-order means a range from about 1 to 99 nm; the submicrometer-order means a range from about 0.1 to 0.99 μm; and the micrometer-order means a range from about 1 to 99 μm.

Further, another carbon substrate such as a diamond substrate can be used instead of the graphite substrate. In this case, a plasma etching process is performed upon the surface of the diamond substrate to decrease the reflectivity.

It will be apparent to those skilled in the art that various modifications and variations can be made in the presently disclosed subject matter without departing from the spirit or scope of the presently disclosed subject matter. Thus, it is intended that the presently disclosed subject matter covers all modifications and variations of the presently disclosed subject matter provided they come within the scope of the appended claims and their equivalents. All related or prior art references described above and in the Background section of the present specification are hereby incorporated in their entirety by reference.

What is claimed is:

1. A heat dissipating material comprising a carbon substrate having a first uneven structure on a surface thereof, a size of said first uneven structure being on the nanometer-order.

2. The heat dissipating material as set forth in claim 1, wherein said carbon substrate further has a second uneven structure on the surface thereof,
said second uneven structure being irregularly-periodic,
a size of said second uneven structure being larger than the size of said first uneven structure.

3. The heat dissipating material as set forth in claim 2, wherein the size of said second uneven structure is on the submicrometer-order or larger than the submicrometer-order.

4. The heat dissipating material as set forth in claim 2, wherein said second uneven structure is a structure where a plurality of grooves are formed on the surface of said carbon substrate.

5. The heat dissipating material as set forth in claim 2, wherein said second uneven structure is a spiked-holder type structure on the surface of said carbon substrate.

6. The heat dissipating material as set forth in claim 1, wherein said carbon substrate comprises a graphite substrate.

7. The heat dissipating material as set forth in claim 6, wherein said graphite substrate comprises a dense graphite substrate.

8. The heat dissipating material as set forth in claim 6, wherein said graphite substrate comprises an insulating graphite substrate.

9. A method for manufacturing a heat dissipating material comprising performing a first process upon a carbon substrate to have a first uneven structure on a surface thereof, a size of said first uneven structure being on the nanometer-order.

10. The method as set forth in claim 9, further performing a second process upon said carbon substrate to have a second uneven structure on the surface thereof,
said second uneven structure having an irregularly-periodic pattern,
a size of said second uneven structure being larger than the size of said first uneven structure.

11. The method as set forth in claim 10, wherein the size of said second uneven structure is on the submicrometer-order or larger than the submicrometer-order.

12. The method as set forth in claim 9, wherein said first process is a plasma etching process.

13. The method as set forth in claim 10, wherein said second uneven structure is a structure where a plurality of grooves are formed on the surface of said carbon substrate.

14. The method as set forth in claim 13, wherein said second process performing comprises:
forming a photoresist pattern layer having said irregularly-periodic pattern on the surface of said carbon substrate by a photolithography process;
etching said carbon substrate by using said photoresist pattern layer to form said grooves; and
removing said photoresist pattern layer after said carbon substrate is etched.

15. The method as set forth in claim 10, wherein said second uneven structure is a spiked-holder type structure on the surface of said carbon substrate.

16. The method as set forth in claim 15, wherein said second process is a mechanical ruling engine cutting process.

17. The method as set forth in claim 15, wherein said second process is a mechanical surface roughening process.

18. The method as set forth in claim 15, wherein said second process is a laser irradiation process.

19. The method as set forth in claim 9, wherein said carbon substrate comprises a graphite substrate.
